(19) United States
(12) Patent Application Publication
(10) Pub. No.: US 2026/0158678 A1
(43) Pub. Date: Jun. 11, 2026

(54) MOUNTING HEAD

(71) Applicant: HANWHA PRECISION MACHINERY CO., LTD., Changwon-si (KR)

(72) Inventor: Kang Je PARK, Changwon-si (KR)

(73) Assignee: HANWHA PRECISION MACHINERY CO., LTD., Changwon-si (KR)

(21) Appl. No.: 18/723,723

(22) PCT Filed: Dec. 22, 2022
(86) PCT No.: PCT/KR2022/021079

§ 371 Date: Jun. 24, 2024

(30) Foreign Application Priority Data
Dec. 23, 2021 (KR) 10-2021-0186603

(51) Int. Cl. B25J 15/06; H10P 72/78

(52) U.S. Cl. CPC B25J 15/0616; H10P 72/78

(57) ABSTRACT

A mounting head according to an embodiment of the present disclosure includes a head main body movable in a vertical direction, a spindle installed on the head main body to be rotatable around a z-axis that is an axis in the vertical direction, an adsorption device installed under the spindle to vacuum-adsorb a semiconductor chip through a follower mechanism, and a housing supporting the follower mechanism to enable the follower mechanism to rotate around the z-axis, in which an air supply/exhaust port is installed in the housing to supply a positive pressure or a negative pressure and communicates with the adsorption device through an air passage, and an elastic body is mounted in the follower mechanism to provide an elastic force to the adsorption device.

### TECHNICAL FIELD

The present disclosure relates to a mounting head of a mounting device for mounting a semiconductor chip on a substrate.

### BACKGROUND ART

A mounting head of a conventional general mounting device includes a head main body movable in a vertical direction, a spindle rotatably mounted on the head main body around a Z-axis, which is a vertical axis, and an adsorption device, such as a collet, a nozzle, etc., for vacuum-adsorbing a semiconductor chip mounted on a bottom portion of the spindle.

To implement high-quality mounting for such a mounting head, it is necessary to always keep an adsorption surface (a bottom surface) of the adsorption device for vacuum-adsorbing the semiconductor chip and a surface of a substrate parallel to each other. Thus, when the adsorption surface (the bottom surface) of the adsorption device for vacuum-adsorbing the semiconductor chip and the surface of the substrate are not parallel to each other, a follower mechanism, for example, disclosed in Japanese Publication Patent Gazette No. 2002-141361, Japanese Publication Patent Gazette No. 2010-27988, or Japanese Publication Patent Gazette No. 2016-51857, may be disposed between the spindle and the adsorption device to make the adsorption surface (the bottom surface) of the adsorption device parallel to the surface of the substrate.

However, in the mounting head including the adsorption device for vacuum-adsorbing the semiconductor chip, a positive pressure and a negative pressure need to be selectively supplied to the adsorption device, and a configuration therefor was not disclosed in the three Japanese Publication Patent Gazettes.

Simply, an air supply/exhaust port for supplying the positive pressure or the negative pressure is provided in the adsorption device, but the adsorption device rotates around the Z-axis, such that when the air supply/exhaust port is provided in the adsorption device, an air pipe connected to the air supply/exhaust port may be pulled in by the rotation of the adsorption device, thereby disturbing a rotational operation of the adsorption device. Moreover, the adsorption device is mounted on a bottom surface of a lower block (an oscillator) of the follower mechanism, but when the air supply/exhaust port is provided in the adsorption device, a weight or a pipe resistance of the adsorption device including the air pipe connected to the air supply/exhaust port increases, thereby obstructing a following operation by oscillation of the lower block (the oscillator). In addition, when the air supply/exhaust port is disposed in the follower mechanism, the rotational operation or following operation of the follower mechanism is disturbed.

Furthermore, in a process of keeping the adsorption device and the surface of the substrate parallel to each other, a rotating tilt of the adsorption device occurring due to the oscillation of the adsorption device needs to be realized without friction with surrounding components.

### DISCLOSURE

### Technical Problem

According to an aspect of the present disclosure, there is provided a mounting head including an adsorption device configured to vacuum-adsorb a semiconductor chip and a follower mechanism configured to parallelize an adsorption surface (a bottom surface) of the adsorption device and a surface of a substrate, in which a positive pressure and a negative pressure may be selectively supplied to the adsorption device without disturbing a rotational operation of the adsorption device and a following operation of the follower mechanism.

According to an aspect of the present disclosure, there is provided a mounting head in which a rotating tilt of an adsorption device may be precisely implemented without friction with surrounding components.

However, these problems are exemplary, and the problems to be solved by the present disclosure are not limited thereto.

### Technical Solution

A mounting head according to an embodiment of the present disclosure includes a head main body movable in a vertical direction, a spindle installed on the head main body to be rotatable around a z-axis that is an axis in the vertical direction, an adsorption device installed under the spindle to vacuum-adsorb a semiconductor chip through a follower mechanism, and a housing supporting the follower mechanism to enable the follower mechanism to rotate around the z-axis, in which an air supply/exhaust port is installed in the housing to supply a positive pressure or a negative pressure, and communicates with the adsorption device through an air passage, and an elastic body is mounted in the follower mechanism to provide an elastic force to the adsorption device.

In the mounting head according to an embodiment of the present disclosure, the follower mechanism may include a piston cylinder mounted to be unmovable in a z-axis direction with respect to the housing and a piston rod arranged in the piston cylinder to move in the z-axis direction, and the elastic body may be arranged between the piston cylinder and the piston rod to provide the elastic force to the piston rod.

In the mounting head according to an embodiment of the present disclosure, the piston cylinder may include a main body portion and a cover portion, the piston rod may include an upper rod and a lower rod, and the elastic body may be arranged between the cover portion and the upper rod.

In the mounting head according to an embodiment of the present disclosure, the follower mechanism may include an upper block including a first following surface having any one of a concave hemisphere shape and a convex hemisphere shape and a lower block including a second following surface having a hemisphere shape, not used by the first following surface, between the concave hemisphere shape and the convex hemisphere shape, the lower block being connected to the elastic body, and as the second following surface follows the first following surface, the lower block may be installed to oscillate with respect to the upper block and the adsorption device may be installed on a bottom surface side of the lower block.

In the mounting head according to an embodiment of the present disclosure, the follower mechanism may further include a piston cylinder and a piston rod arranged in the piston cylinder to move in the z-axis direction, the piston cylinder may be installed to be rotatable around the z-axis with respect to the housing, the piston cylinder may be installed to be unmovable in the z-axis direction with respect to the housing, the upper block may be fixed to a bottom portion of the piston cylinder, the lower block connected to the piston rod may be installed in a bottom portion of the piston rod to oscillate with respect to the upper block, and the lower block may be spaced apart from the upper block by the elastic body.

Other aspects, features and advantages than described above will become apparent from the detailed description, claims, and drawings for carrying out the present disclosure below.

### Advantageous Effects

A mounting head according to an embodiment of the present disclosure may selectively supply a positive pressure and a negative pressure to an adsorption device without disturbing a rotational operation of the adsorption device or a following operation of a follower mechanism.

Moreover, the mounting head according to an embodiment of the present disclosure may enable precise tilting of the adsorption device under minimized interference with surrounding components.

Effects of the present disclosure are not limited to the effects mentioned above, and other effects not mentioned will be clearly understood by those of ordinary skill in the art from the detailed description and description of the claims.

### DESCRIPTION OF DRAWINGS

FIG. 1 is a conceptual view showing an overall structure of a mounting head according to an embodiment of the present disclosure.

FIG. 2 is a perspective view showing a follower mechanism supported by a housing, according to an embodiment of the present disclosure.

FIG. 3 is an exploded perspective view of FIG. 2.

FIG. 4 is a cross-sectional view cut along line A-A of FIG. 2.

FIG. 5A shows an upper block and a lower block spaced apart from each other, according to an embodiment of the present disclosure.

FIG. 5B shows a tilting axis Za of a lower block tilted to a side, according to an embodiment of the present disclosure.

FIG. 5C shows a tilting axis Zb of a lower block tilted to another side, according to an embodiment of the present disclosure.

### MODE FOR INVENTION

The present disclosure may have various modifications thereto and various embodiments, and thus particular embodiments will be illustrated in the drawings and described in detail in a detailed description. It should be understood, however, that this is not intended to limit the present disclosure to a particular embodiment, and should be understood to include all changes, equivalents, and alternatives falling within the spirit and scope of the present disclosure. To describe the present disclosure, the same component, even when shown in different embodiments, will be denoted by the same reference numeral.

Hereinafter, embodiments of the present disclosure will be described in detail with reference to the accompanying drawings, and in description with reference to the drawings, the same or corresponding components are given the same reference numerals, and redundant description thereto will be omitted.

In the following embodiments, the terms such as first, second, etc., have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the drawings, the size of components may be exaggerated or reduced for convenience of description. For example, the size and thickness of each component shown in the drawings are shown for convenience of description, and thus the present disclosure is not necessarily limited to the illustration.

When a certain embodiment may be implemented otherwise, a particular process order may be performed differently from the order described. For example, two processes described in succession may be performed substantially simultaneously, or may be performed in an order reverse to the order described.

The term used herein is used to describe particular embodiments, and is not intended to limit the present disclosure. Herein, it should be understood that the term “include”, “have”, or the like used herein is to indicate the presence of features, numbers, steps, operations, components, parts, or a combination thereof described in the specifications, and does not preclude the presence or addition of one or more other features, numbers, steps, operations, components, parts, or a combination thereof.

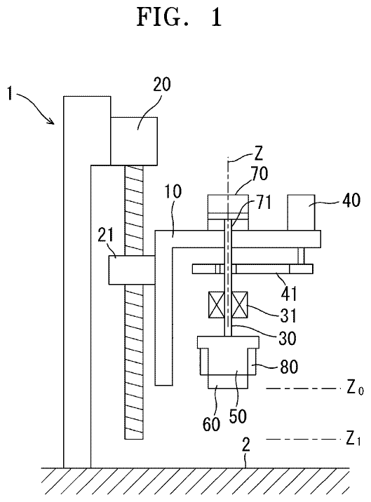

FIG. 1 conceptually shows an overall structure of a mounting head according to an embodiment of the present disclosure.

A mounting head 1 shown in FIG. 1 may include a head main body 10 movable in a vertical direction. When a ball screw mechanism 21 operates by driving of a motor 20, the head main body 10 may move in the vertical direction.

In the head main body 10, a spindle 30 may be installed to be rotatable around a Z-axis, which is a vertical axis. When a belt device 41 operates by driving of the motor 40, the spindle 30 may rotate around the Z-axis.

Under the spindle 30, a collet 60 may be installed as an adsorption device for vacuum-adsorbing a semiconductor chip through a follower mechanism 50. A top of the spindle 30 may be connected to a cylinder rod 71 of an air cylinder mechanism 70. The air cylinder mechanism 70 may be filled with air of a predetermined pressure and function as an air spring.

As will be described later in detail, in a following operation of the follower mechanism 50, the spindle 30 may be lowered together with the head main body 10 by driving of the motor 20 to cause a bottom surface of the collet 60 to touch a surface 2 of a substrate and in this state, may be further lowered by a predetermined amount (about 0.5 mm). In this case, the spindle 30 may move upwardly with respect to the head main body 10 by an air spring function of the air cylinder mechanism 70. Upon completion of the following operation, when the spindle 30 is raised together with the head main body 10, the spindle 30 may move downwardly with respect to the head main body 10 by the air spring function of the air cylinder mechanism 70, thus returning to an initial position (an original position).

As such, according to the current embodiment, the spindle 30 may rotate around the Z-axis with respect to the head main body 10 and may also move in a Z-axis direction. In the current embodiment, the spindle 30 may be guided by a spindle guide 31 in rotation or movement thereof, such that the rotation or movement may be facilitated.

The follower mechanism 50 may be supported on a housing 80 so as to be rotatable around the Z-axis. A stopper mechanism may be disposed between the head main body 10 and the housing 80.

The follower mechanism 50 will be described in detail.

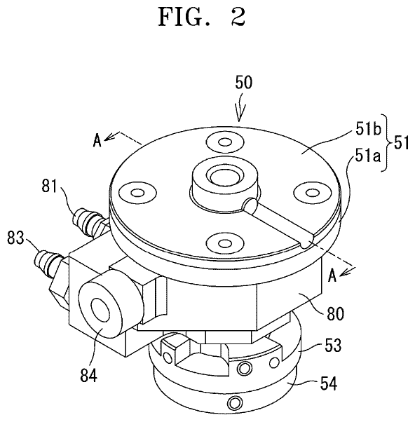

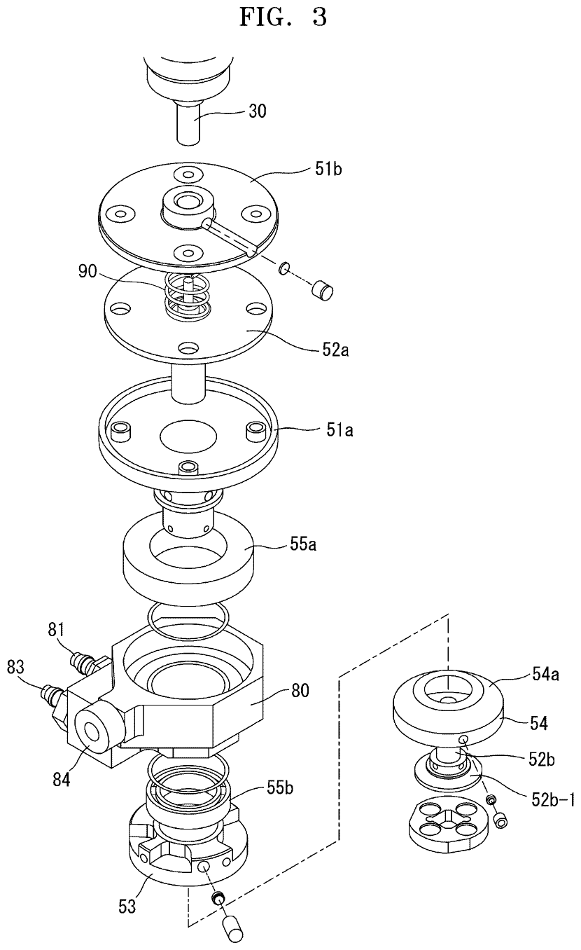

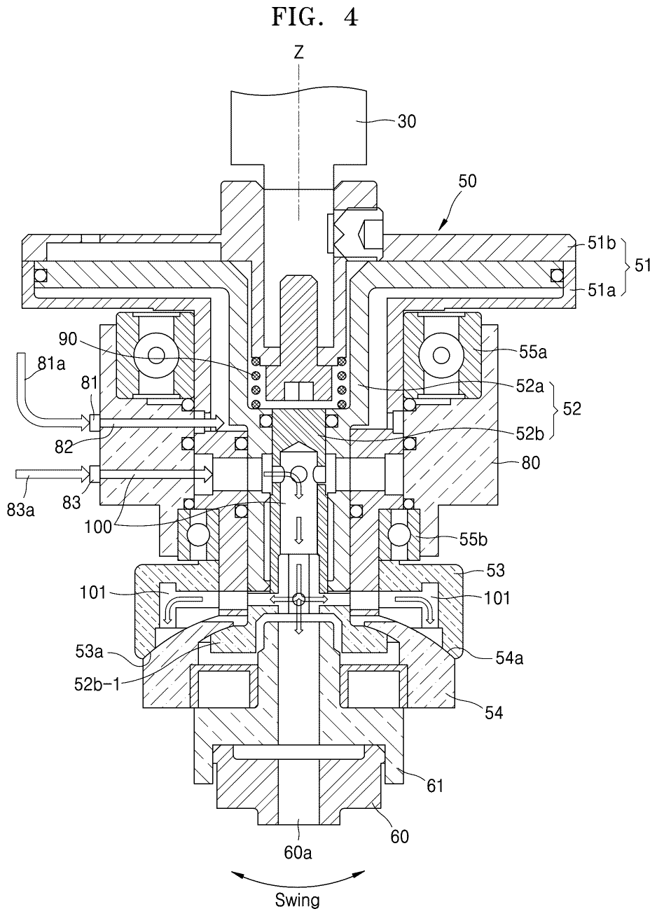

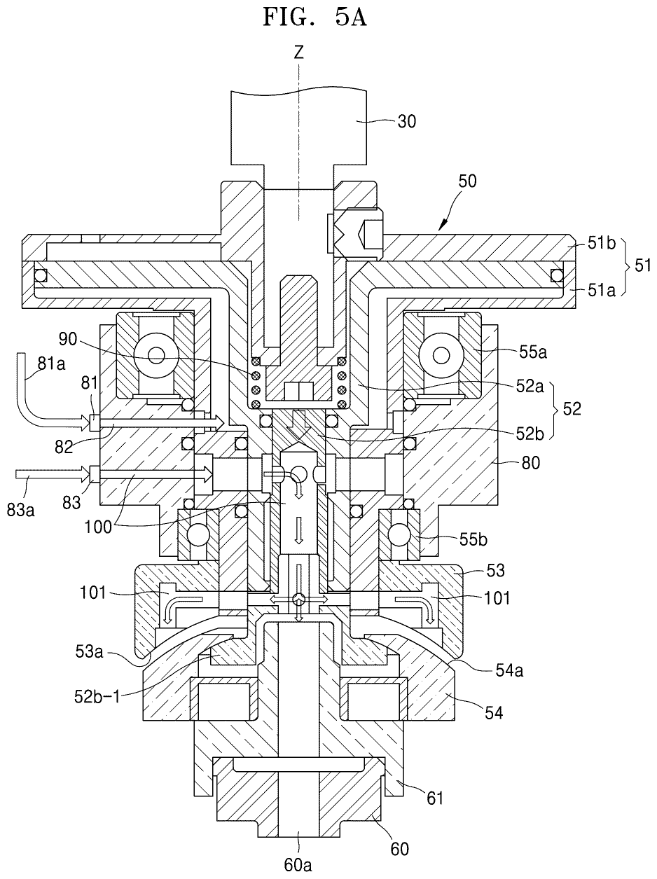

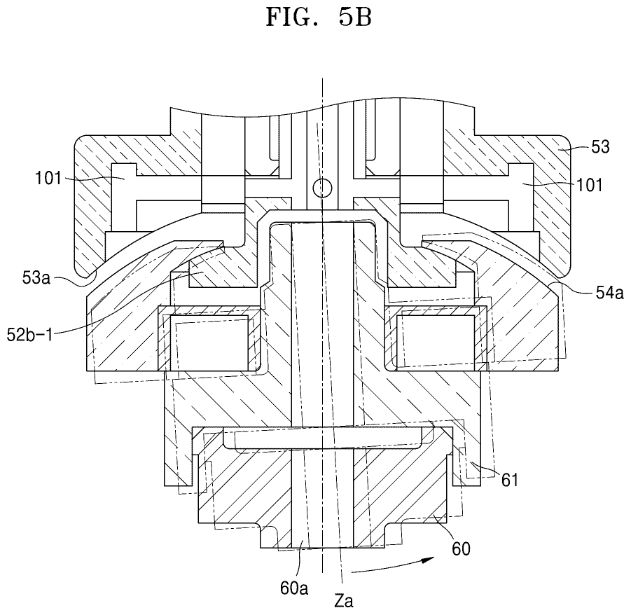

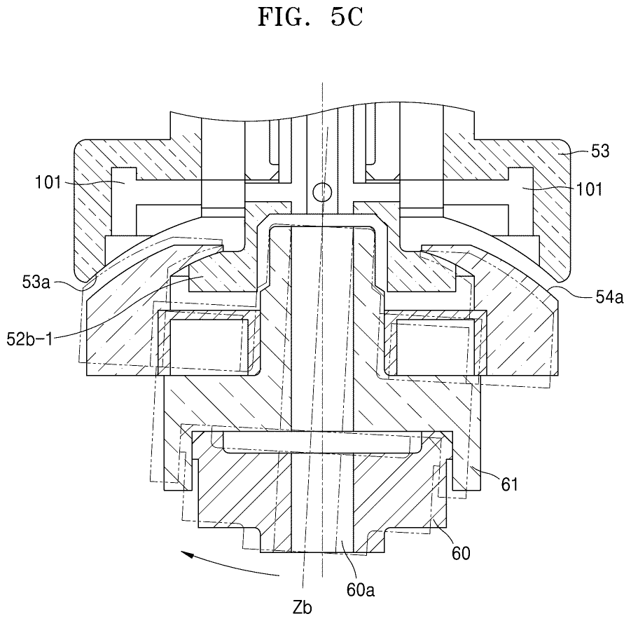

FIG. 2 is a perspective view showing the follower mechanism 50 supported by the housing 80, FIG. 3 is an exploded perspective view of FIG. 2, and FIG. 4 is a cross-sectional view cut along line A-A of FIG. 2. In FIG. 4, the collet 60 is further shown. FIG. 5A shows an upper block and a lower block spaced apart from each other, according to an embodiment of the present disclosure. FIG. 5B shows a tilting axis Za of a lower block tilted to a side, according to an embodiment of the present disclosure. FIG. 5C shows a tilting axis Zb of a lower block tilted to another side, according to an embodiment of the present disclosure.

The follower mechanism 50 may include a piston cylinder 51, a piston rod 52, an upper block 53, and a lower block 54.

The piston cylinder 51 may include a combination of a main body portion 51a and a cover portion 51b and may be installed to be rotatable around the Z-axis with respect to bearings 55a and 55b disposed in two upper and lower places.

A bottom portion of the spindle 30 may be fixed to the cover portion 51b that is a top portion of the piston cylinder 51. As a result, when the spindle 30 rotates around the Z-axis, the piston cylinder 51 may also rotate around the Z-axis. The piston cylinder 51 may be installed to be unmovable in the Z-axis direction with respect to the housing 80.

The piston rod 52 may include an upper rod 52a and a lower rod 52b that are formed integrally, and may be disposed in the piston cylinder 51 to be rotatable in the Z-axis direction.

An air supply port 81 for supplying a positive pressure (pressurized air) may be installed in the housing 80. The positive pressure (e.g., about 0.5 MPa) supplied to the air supply port 81 may be supplied to the piston cylinder 51 through a positive pressure passage 82, and the piston rod 52 may be pressed in an upward direction in the Z-axis direction by the positive pressure. To sufficiently secure a pressing force in the upward direction in the Z-axis direction due to the positive pressure, top portions of the piston cylinder 51 and the piston rod 52 may be enlarged in a flange shape.

The upper block 53 may include, on a bottom surface thereof, a first following surface 53a that is a concave hemisphere, and may be fixed to a bottom portion of the main body portion 51a of the piston cylinder 51.

The lower block 54 may include, on a bottom surface thereof, a second following surface 54a that is a convex hemisphere, and may supported to oscillate on a support portion 52b-1 on a flange formed on a bottom portion of the lower rod 52b. As the second following surface 54a of the lower block 54 follows the first following surface 53a of the upper block 53, the lower block 54 may be installed to oscillate with respect to the upper block 53.

As shown in FIG. 4, the collet 60, which is an adsorption device, may be installed on a bottom surface side of the lower block 54 through a collet holder 61.

An air supply/exhaust port 83 for supplying a positive pressure or a negative pressure may be installed in the housing 80. As shown in FIG. 4, the air supply/exhaust port 83 may communicate with an adsorption hole 60a of the collet 60 through an air passage 100. Thus, when a negative pressure (e.g., about −0.1 MPa) is supplied from the air supply/exhaust port 83, the negative pressure may be supplied to the adsorption hole 60a of the collet 60 through the air passage 100, such that a semiconductor chip may be vacuum-adsorbed in the collet 60. Thereafter, when a positive pressure (e.g., about 0.2 MPa) is supplied to the air supply/exhaust port 83, the positive pressure may be supplied to the adsorption hole 60a of the collet 60 through the air passage 100, such that the semiconductor chip may leave the collet 60 and may be mounted on the substrate.

In such series of mounting operations, the positive pressure may be supplied into the piston cylinder 51 from the air supply port 81 through the positive pressure passage 82 at all times, and the piston rod 52 may be pressed in the upward direction in the Z-axis direction by the positive pressure. Then, the support portion 52b-1 of the piston rod 52 may strongly push the lower block 54 upwardly, such that the lower block 54 may be closely fixed to the upper block 53, thus entering a locked state where oscillation is not possible.

In the current embodiment, the air passage 100 may pass over a vertical central axis (Z axis) of the piston rod 52 (the lower rod 52a) and communicate with the adsorption hole 60a of the collet 60. In the current embodiment, the upper block 53 may include a branch air passage 101 which is branched from the air passage 100 and communicates with the first following surface 53a.

As will be described below in detail, in the following operation of the follower mechanism 50, when the positive pressure is supplied to the air supply/exhaust port 83, the positive pressure may be radially ejected from the first following surface 53a toward the second following surface 54a through the air passage 100 and the branch air passage 101. Thus, the locked state may be released such that the lower block 54 may enter a lock-released state in which the lower block 54 may oscillate with respect to the upper block 53.

The following operation of the follower mechanism 50 will be described. In the current embodiment, as preparation for the following operation, a bottom portion of the air passage 100 communicating with the collet 60 or the adsorption hole 60a may be blocked. For example, to block the bottom portion of the air passage 100, the collet 60 may be replaced with a dummy collet (not shown). The dummy collet may have the same exterior shape as the collet 60, and may have a blocked bottom portion of the air passage 100. The bottom portion of the air passage 100 or the adsorption hole 60a may be blocked with a variable blocking portion, a valve, etc., by using the collet 60, without using the dummy collet.

Thus, the following description will be made assuming that the collet 60 is used.

A height position of the bottom surface of the collet 60 before the following operation may be a position Z0 (a home position) as shown in FIG. 1. In the following operation, the head main body 10 may be lowered at high speed (e.g., about 600 mm/s) until the height position of the bottom surface of the collet 60 is a position Z1.

When the height position of the bottom surface of the collet 60 is the position Z1, supply of the positive pressure from the air supply port 81 may be stopped and the positive pressure passage 82 may be opened to the atmosphere. Thus, the piston rod 52 may not be pressed in the upward direction in the Z-axis direction, and the fixation of the lower block 54 to the upper block 53 may be released.

Thus, the positive pressure from the air supply/exhaust port 83 may be supplied temporarily (e.g., for about 0.5 seconds). This positive pressure may be radially ejected downwardly from the first following surface 53a toward the second following surface 54a through the positive pressure air passage 100 and the branch air passage 101. Thus, the lower block 54 may enter the lock-released state in which the lower block 54 may oscillate with respect to the upper block 53.

Until the bottom surface of the collet 60 touches the surface 2 of the substrate, the head main body 10 may be lowered at low speed (e.g., about 2 mm/s).

Whether the bottom surface of the collet 60 touches the surface 2 of the substrate may be detected by a well-known touch sensor. By further lowering the head main body 10 by a predetermined amount (about 0.5 mm) after the bottom surface of the collet 60 touches the surface 2 of the substrate, the collet 60 may push the surface 2 of the substrate for a predetermined time (e.g., about 2 seconds). Thus, the lower block 54 of the follower mechanism 50 holding the collet 60 may move to follow the surface 2 of the substrate, and the bottom surface (the adsorption surface) of the collet 60 and the surface 2 of the substrate may be parallelized to each other.

Thereafter, the positive pressure from the air supply/exhaust port 83 may be supplied temporarily (e.g., for about 2 seconds). With this negative pressure, the lower block 54 of the follower mechanism 50 may be pulled to the upper block 53 and thus may be temporarily locked. Thereafter, the positive pressure may be supplied to the air supply port 81. The piston rod 52 may be pressed by this positive pressure in the upward direction in the Z-axis direction, such that the support portion 52b-1 of the piston rod 52 strongly pushes up the lower block 54 up which is then closely fixed to the upper block 53, thus entering a locked state where oscillation is not possible. Last, until the height position of the bottom surface of the collet 60 is the position Z0, the head main body 10 may be raised.

As such, the mounting head 1 according to the current embodiment may include the housing 80 supporting the follower mechanism 50 such that the follower mechanism 50 is rotatable around the Z axis, and the air supply port 81 and the air supply/exhaust port 83 may be disposed on the housing 80. Thus, as the housing 80 does not rotate in spite of the rotation of the follower mechanism 50 and the collet 60 around the Z axis due to the rotation of the spindle 80, air pipes 81a and 83a connected to the air supply port 81 and the air supply/exhaust port 83 may not rotate.

As such, according to the current embodiment, without disturbing the rotational operation of the collet 60 or the following operation of the follower mechanism 50, the positive pressure and the negative pressure may be selectively supplied to the collet 60. Moreover, in the current embodiment, as the air supply port 81 or the air supply/exhaust port 83 is not disposed in the follower mechanism 50 or the collet 60, they may be miniaturized and lightweight and the rotational operation of the collet 60 or the following operation of the follower mechanism 50 may be smoothly performed.

While the first following surface 53a on the bottom surface of the upper block 53 is a concave hemisphere and the second following surface 54a on the top surface of the lower block 54 is a convex hemisphere in the current embodiment, on the other hand, the first following surface 53a on the bottom surface of the upper block 53 may be a convex hemisphere and the second following surface 54a on the top surface of the lower block 54 may be a concave hemisphere. An adsorption nozzle instead of the collet 60 may be used as the adsorption device.

The follower mechanism 50 having an elastic body 90 and a function thereof will be described below.

Referring to FIGS. 3 to 5, the elastic body 90 may be disposed on the collet 60, which is the adsorption device, in the follower mechanism 50 to provide an elastic force to the collet 60. The elastic body 90 may be disposed between the piston cylinder 51 and the piston rod 52 to provide the elastic force to the piston rod 52.

More specifically, the elastic body 90 may be disposed between a central bottom portion of the cover portion 51b and the upper rod 52a. The elastic body 90 may provide the elastic force to the upper rod 52a of the piston rod 52 with respect to the fixed piston cylinder 51. The upper rod 52a receiving the elastic force of the elastic body 90 may be formed integrally with the upper rod 52a to transmit the elastic force to the lower rod 52b connected to the elastic body 90, and the lower rod 52b may transmit the elastic force to the lower block 54 supported to oscillate on the support portion 52b-1 on the flange formed in the bottom portion of the lower rod 52b.

Thus, the lower block 54 may be pressed in the downward direction along the Z axis by a tensile force of the elastic body 90, such that as shown in FIG. 5, a gap G may be formed between the lower block 54 and the upper block 53 having the fixed position.

A structure of the second following surface 54a of the lower block 54 as the convex hemisphere, which corresponds to the first following surface 53a of the upper block 53 as the concave hemisphere, i.e., a gyro structure may generally have a degree of rotational freedom while maintaining contact between spherical surfaces and match accuracies by imitating the accuracy of a target. As a problem that may be faced at this time, fixation of gyro spheres may be easily implemented, but it may not be easy to secure a release force for releasing the fixation of the gyro spheres.

The positive pressure supplied through the air supply/exhaust port 83 may be radially ejected downwardly from the first following surface 53a toward the second following surface 54a through the positive pressure air passage 100 and the branch air passage 101, such that the lower block 54 may enter the lock-released state in which the lower block 54 may oscillate with respect to the upper block 53.

However, for the oscillation of the lower block 54 without friction with the upper block 53 by releasing the lock through overcoming mechanical friction merely with the force of air, i.e., the air force, there may be a limitation in the force due to spatial constraints. That is, due to a small area of the second following surface 54a to which the air pressure is applied, a high air force may not be secured, failing to push the second following surface 54a and the lower block 54, which are the gyro spheres.

Therefore, to completely remove friction between the gyro spheres, the action of a physical force that is more powerful and directly acts than the force of air, i.e., an air floating force, such that according to the current embodiment, a higher physical force than the force of air, i.e., the air floating force may be secured by the tensile force of the elastic body 90. As such, as the tensile force of the elastic body 90, together with the force of air, the gap G may be generated between the first following surface 53a and the second following surface 54a as shown in FIG. 5, such that tilting degrees of rotational tilting axes Za and Zb of the lower block 54 and the collet 60 may increase and friction between the spheres may be reduced, due to a space secured through the gap G, thereby significantly improving the accuracy and precision of following on the surface of the substrate of the collet 60 so as to parallelize the bottom surface of the collet 60 as the adsorption device to the surface 2 of the substrate.

As such, the present disclosure has been described with reference to the embodiments shown in the drawings, but this is merely an example. It would be fully understood by those of ordinary skill in the art that various modifications and other equivalent embodiments are possible from the embodiments. Therefore, the true technical scope of the present disclosure should be defined by the appended claims.

Specific technical details described in the embodiments are examples, and do not limit the technical scope of the embodiments. In order to briefly and clearly describe the description of the present disclosure, the description of conventional general techniques and configurations may be omitted. Connections of lines or connection members between components shown in the drawings are illustrative of functional connections and/or physical or circuit connections, and in practice, may be expressed as alternative or additional various functional connections, physical connections, or circuit connections. In addition, when there is no specific mentioning, such as “essential” or “important”, it may not be a necessary component for the application of the present disclosure.

A designator “the” or similar designators described in the description and the claims may refer to both singular and plural, unless otherwise specifically limited. In addition, when the range is described in the embodiments, the range includes the present disclosure to which an individual value falling within the range is applied (unless stated otherwise), and is the same as the description of an individual value constituting the range in the description of the present disclosure. When there is no apparent description of the order of operations constituting the method according to the embodiments or a contrary description thereof, the operations may be performed in an appropriate order. However, the present disclosure is not necessarily limited according to the describing order of the operations. The use of all examples or exemplary terms (for example, etc.) in the present disclosure are to simply describe the present disclosure in detail, and unless the range of the present disclosure is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

1. A mounting head comprising:
a head main body movable in a vertical direction;
a spindle installed on the head main body to be rotatable around a z-axis that is an axis in the vertical direction;
an adsorption device installed under the spindle to vacuum-adsorb a semiconductor chip through a follower mechanism; and
a housing supporting the follower mechanism to enable the follower mechanism to rotate around the z-axis,
wherein an air supply/exhaust port is installed in the housing to supply a positive pressure or a negative pressure and communicates with the adsorption device through an air passage, and
an elastic body is mounted in the follower mechanism to provide an elastic force to the adsorption device.

2. The mounting head of claim 1, wherein the follower mechanism comprises:
a piston cylinder mounted to be unmovable in a z-axis direction with respect to the housing; and
a piston rod arranged in the piston cylinder to move in the z-axis direction, and
the elastic body is arranged between the piston cylinder and the piston rod to provide the elastic force to the piston rod.

3. The mounting head of claim 2, wherein the piston cylinder comprises a main body portion and a cover portion,
the piston rod comprises an upper rod and a lower rod, and
the elastic body is arranged between the cover portion and the upper rod.

4. The mounting head of claim 1, wherein the follower mechanism comprises:
an upper block comprising a first following surface having any one of a concave hemisphere shape and a convex hemisphere shape; and
a lower block comprising a second following surface having a hemisphere shape, not used by the first following surface, between the concave hemisphere shape and the convex hemisphere shape, the lower block being connected to the elastic body, and
as the second following surface follows the first following surface, the lower block is installed to oscillate with respect to the upper block and the adsorption device is installed on a bottom surface side of the lower block.

5. The mounting head of claim 4, wherein the follower mechanism further comprises a piston cylinder and a piston rod arranged in the piston cylinder to move in the z-axis direction,
the piston cylinder is installed to be rotatable around the z-axis with respect to the housing,
the piston cylinder is installed to be unmovable in the z-axis direction with respect to the housing,
the upper block is fixed to a bottom portion of the piston cylinder,
the lower block connected to the piston rod is installed in a bottom portion of the piston rod to oscillate with respect to the upper block, and
the lower block is spaced apart from the upper block by the elastic body.
